(19) United States
(12) Patent Application Publication
(10) Pub. No.: US 2023/0085997 A1
(43) Pub. Date: Mar. 23, 2023

(54) METHODS AND APPARATUS TO IMPROVE ADHESION BETWEEN METALS AND DIELECTRICS IN CIRCUIT DEVICES

(71) Applicant: Intel Corporation, Santa Clara, CA (US)

(72) Inventors: Yi Yang, Gilbert, AZ (US); Eungnak Han, Portland, OR (US); Suddhasattwa Nad, Chandler, AZ (US); Marcel Wall, Phoenix, AZ (US)

(21) Appl. No.: 17/483,439

(22) Filed: Sep. 23, 2021

(51) Int. Cl. H05K 3/38

(52) U.S. Cl. CPC H05K 3/386

(57) ABSTRACT

Methods and apparatus to improve adhesion between metals and dielectrics in circuit devices are disclosed. An apparatus includes a metal layer, a dielectric layer adjacent the metal layer, and a polymeric bonding layer at an interface between the metal layer and the dielectric layer. A polymer molecule in the polymeric bonding layer including an R1 group, an R2 group, and a polymer chain extending between the R1 group and the R2 group. The R1 group is different than the R2 group. The polymeric bonding layer is bonded to the metal layer via the R1 group. The polymeric bonding layer is bonded to the dielectric layer via the R2 group.

### FIELD OF THE DISCLOSURE

This disclosure relates generally to electrical circuit devices and, more particularly, to methods and apparatus to improve adhesion between metals and dielectrics in circuit devices.

### BACKGROUND

Many electrical circuit devices include substrates (e.g., integrated circuit (IC) package substrates, printed circuit boards (PCB), etc.) that have metal traces or interconnects formed of conductive metal between layers of dielectric materials. Interfacial adhesion between the metal and the dielectric materials is often achieved by a roughening of the surface of the metal prior to the addition of the dielectric material. Such roughened metal surfaces provide anchor points to which a laminated dielectric can mechanically attach.

Demand for higher performance devices drives the need for a package transmission line or interconnect to operate at ever increasing frequencies and to maintain the package insertion loss budget. Demand for high speed input/output (HISO) depends upon metal interconnects being relatively smooth for signal integrity because, at high frequencies, a significant portion of a signal is conducted close to the surface of the metal interconnect. Thus, the roughening of metal traces or interconnects is no longer a viable option to enable the adhesion between such metals and dielectric materials.

### BRIEF DESCRIPTION OF THE DRAWINGS

FIG. 1 illustrates an example substrate constructed in accordance with teachings disclosed herein.

FIG. 2 illustrates an example supramolecular bonding film disposed on a metal layer of the example substrate of FIG. 1 prior to the attachment of an interfacing dielectric layer.

FIG. 3 illustrates the example supramolecular bonding film of FIG. 2 after undergoing an initial cross-linking process.

FIGS. 4-6 represent three alternative example modes of bonding between a dielectric layer and the supramolecular bonding film of FIGS. 2 and 3.

FIG. 7 illustrates another example supramolecular bonding film.

FIG. 8 is a flowchart representative of an example method of manufacturing the example substrate of FIG. 1 using the example supramolecular bonding film of FIGS. 2-6 and/or FIG. 7.

The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular. In general, the same reference numbers will be used throughout the drawing(s) and accompanying written description to refer to the same or like parts. As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another. Notwithstanding the foregoing, in the case of a semiconductor device, “above” is not with reference to Earth, but instead is with reference to a bulk region of a base semiconductor substrate (e.g., a semiconductor wafer) on which components of an integrated circuit are formed. Specifically, as used herein, a first component of an integrated circuit is “above” a second component when the first component is farther away from the bulk region of the semiconductor substrate than the second component. As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween. As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

### DETAILED DESCRIPTION

Many electric circuit substrates (e.g., IC package substrates, PCBs, etc.) include metal (e.g., copper) traces and/or interconnects positioned between organic dielectric layers (e.g., an epoxy-containing matrix). As demand for higher performance devices continues to rise, there is a need to maintain the metal traces and/or interconnects relatively smooth so as not to degrade signals transmitted thereby. As such, there is a need to enable the adhesion of the dielectric layers to the metal without roughening the surface of the metal. Where a mechanical attachment (based on a roughened metal surface) is not available, adhesion can be achieved through the use of a chemical adhesive layer at the metal/dielectric interface.

One approach to adhere an organic dielectric to a relatively smooth metal (copper) surface is by using organic adhesion promotors that are initially formed in a deposition solution that is added as a film onto the copper surface by either spraying the solution thereon or dipping the component into a bath of the solution. In this approach the film growth is driven by the copper-ligand complexation at the copper surface that induces a three-dimensional intermolecular polymerization to form the bulk film matrix. This organic adhesion promotor approach begins with a tri-functional group ended monomer in the deposition solution. Inasmuch as all functionalities are gathered into one molecular structure, this approach limits the flexibility of the molecular design and synthesis. For instance, particular functional groups that provide the desired adhesion performance may not practically be utilized because of the other functional groups that need to be included in the deposition solution. A further limitation of this organic adhesion promotor approach is that the resulting film matrix includes highly disordered three-dimensional stack-ups that arise from the intermolecular polymerization and complexation. Such disordered stack-ups can result in film defects and low bonding density, which can deleteriously impact the quality of the adhesion between the copper and the dielectric.

An alternative approach to bonding a dielectric to a non-roughened copper surface is through the use of inorganic adhesion promotors. Inorganic adhesion promotors on a copper surface act as a diffusion barrier to prevent oxidation of the copper and can be deposited by sputtering or chemical vapor deposition. While such inorganic adhesion promotors provide a well-defined hermetic seal layer to the copper, the bonding strength between the inorganic adhesion promotors and copper, as well as the intra-bonding within the film matrix, is typically too strong to be removed by subsequent wet etching processes. As such, it is difficult to pattern the copper to form traces and/or other metallization structures for desired interconnects. It is still possible to etch the copper (and the inorganic adhesion promotors) through dry etching processes. However, dry etching techniques are much more expensive with their viability dependent on the equipment and process maturity in connection with the manufacturable scale of the desired end product(s).

Examples disclosed herein provide an improved technique to bond a metal substrate (e.g., copper) and an organic dielectric through the use of a linear polymeric structure that densely attaches to the metal surface in a highly oriented, self-assembled manner. As used herein, “self-assembly” means that polymer molecules arrange themselves in a particular and expected manner based on the inherent characteristics and/or properties (structural and/or chemical) of the polymer molecules. The self-assembly of the polymer molecules disclosed herein involve the molecules bonding with or grafting to the metal (e.g., copper) surface in a manner that results in lengths of the polymer molecules substantially consistently or uniformly extending away from the metal surface. More particularly, in some examples, the molecular structure of the linear polymer molecules has multiple different functional groups including a functional group R1 that chemically bonds with the copper surface and a functional group R2 that chemically bonds with the organic dielectric. For the sake of brevity, the R1 functional group is sometimes referred to herein as the R1 group or simply R1. Likewise, the R2 functional group is sometimes referred to herein as the R2 group or simply R2. The R1 and R2 groups are separated by a full length of a linear polymer chain. R1 and R2 are sometimes referred to as “head groups” or “end groups” of the polymer molecule, while the interconnecting polymer chain is referred to as the “polymer backbone.” Further, the R1 and R2 groups can alternatively be referred to as R1 and R2 moieties.

R1 is a strong electron-donating group to energy-favorably bond with the copper to form a coordination complex with copper ions. Further, the bonding of the R1 group to the copper results in the linear structure of the polymer molecules substantially uniformly extending away from (e.g., generally perpendicular to) the copper surface with the R2 group at a distal end of the linear polymer structure. As a result, the R2 group is oriented in a direction to favorably bond with an organic dielectric layer positioned adjacent the surface of the polymeric film that is distal from the copper surface. In some examples, the R2 group is chemically inert to the rest of the linear polymer molecule.

In some examples, a functional group R3 (sometimes referred to herein as the R3 group, the R3 moiety, or simply R3) is included in segregated blocks of the linear polymer molecule as a side group that protrudes from the main polymer chain extending between R1 and R2. The R3 group remains unreactive during the initial polymer deposition or grafting to the copper surface. However, during post processing (e.g., via heating and/or catalyzing of a cross-linking process), the R3 side group is involved in cross-linking reactions that increase the density of the polymer matrix. Furthermore, after dielectric lamination, any R3 moieties that were not previously cross-linked can serve as a reactive group (in combination with R2) to bond with the organic matrix of the dielectric layer during a full cure process.

Unlike the organic adhesion promotor approach discussed above, the example linear polymer molecules disclosed herein are synthesized prior to the deposition or grafting onto a copper surface. As a result, example linear polymer structures disclosed herein provide more reaction sites along the polymer chain than is possible using the tri-functional group ended monomers of the organic adhesion promotor approach. Thus, example linear polymer structures disclosed herein allow for much greater flexibility in the chemical structure of the polymer, thereby enabling the use of functionalities that provide desired adhesion performance that would not otherwise be possible. Further, the linear structure of the example polymer molecules disclosed herein along with the cross-linking side groups provides for a denser and more uniform matrix, thereby improving adhesion and reducing film defects.

Examples disclosed herein can be used in IC packages, printed circuit boards (PCBs) and/or other substrates used in circuit devices. Such circuit devices can be any type of electronic and/or computer device such as, for example, desktop computers, laptop computers, smartphones, tablets, Internet of Things devices, etc.

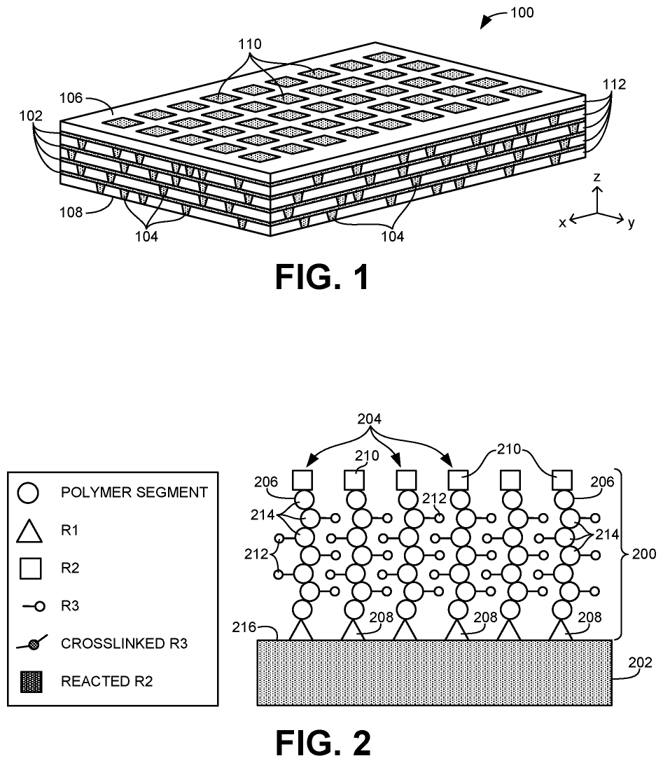

FIG. 1 illustrates an example substrate 100 constructed in accordance with teachings disclosed herein. In some examples, the substrate 100 is a package substrate of an IC package. In other examples, the substrate 100 is a PCB onto which one or more IC packages may be attached. As shown in the illustrated example, the substrate 100 includes metallization structures that are surrounded and supported by one or more insulator materials (e.g., an organic dielectric). More particularly, in this example, the metallization structures are defined by multiple different metal layers 102 corresponding to patterned conductive traces and/or conductive planes that extend parallel to the xy plane of the xyz coordinate system shown in the illustrated example. In the illustrated example of FIG. 1, four different metal layers 102 are shown. However, in other examples, any other suitable number of metal layers 102 may be included in the substrate 100. In some examples, the substrate 100 includes only a single metal layer 102.

In some examples, the metallization structures within the example substrate 100 are further defined by multiple conductive vias 104 that extend in the z direction of the xyz coordinate system between adjacent ones of the metal layers 102. In some examples, the metal layers 102 and the metal vias 104 are interconnected in a manner that provides electrical interconnections between electrical components that may be attached one or both sides 106, 108 of the substrate 100 through associated conductive contacts 110 (e.g., pads, bumps, etc.). In this example, the metal layers 102 and interconnecting vias 104 include copper. In some examples, portions or all of the metal layers 102 and/or the vias 104 may include any other suitable conductive material (e.g., aluminum, nickel, gold, silver, etc.).

As noted above, the metallization structures of the example substrate 100 are surrounded and supported by one or more insulator materials (e.g., an organic dielectric). More particularly, as shown in the illustrated example, the substrate 100 includes multiple different organic dielectric layers 112 disposed in an alternating pattern with the metal layers 102. The organic dielectric layers 112 facilitate the electrical isolation of different portions of the metal layers 102 and interconnecting vias 104. In some examples, the organic dielectric layers 112 include any suitable type of dielectric compound (e.g., polyimide (PI), polytetrafluoroethylene (PTFE), Build-up Film (in general, any of various silica particle filled epoxy materials), a liquid crystal polymer (LCP), and polyetheretherketone (PEEK), etc.) and/or any suitable type of dielectric laminate (e.g., FR4, FR5, bismaleimide triazine (BT) resin, etc.).

In this example, the organic dielectric layers 112 are bonded to the metal layers 102 and/or to the vias 104 without roughening the metal layers 102 and/or the vias 104. To achieve relatively high adhesion performance at the interface of the metal and the dielectric when the metal surface is relatively smooth (e.g., non-roughened) in such examples, a polymeric bonding film is first added to the metal surface that is structured to chemically bond with the metal surface using a functional group R1 of the polymer molecules of the film. The polymer molecules of the film further include a functional group R2 that chemically bonds with the dielectric layers 112.

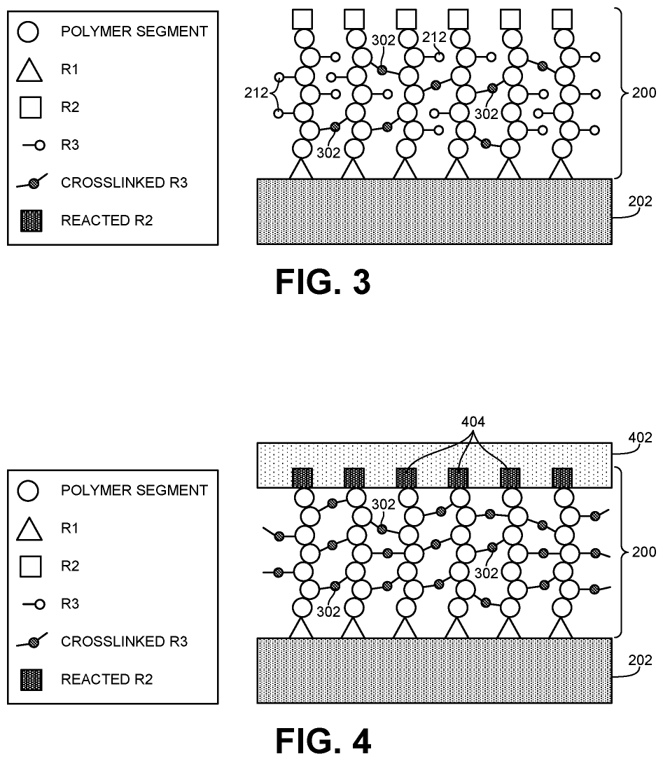

FIGS. 2-6 illustrate various stages in the fabrication of the example substrate 100 of FIG. 1. More particularly, FIG. 2 illustrates an example supramolecular bonding film or layer 200 disposed on a metal substrate 202 (e.g., corresponding to a surface of the metallization structures within the example substrate 100 of FIG. 1) prior to the attachment of an interfacing dielectric layer (e.g., an adjacent one of the organic dielectric layers 112 of FIG. 1). FIG. 3 illustrates the supramolecular bonding film or layer 200 of FIG. 2 after undergoing an initial cross-linking process. FIGS. 4-6 illustrate three alternative example modes of bonding between a dielectric layer 402 (e.g., corresponding to one of the organic dielectric layers 112 of FIG. 1) and the supramolecular bonding layer 200. For purposes of explanation, the metal substrate 202 will be described as a copper substrate. However, in other examples, the metal substrate 202 may be a different conductive metal with the supramolecular bonding layer 200 correspondingly designed to bond with such a metal.

In the illustrated example of FIG. 2, the copper substrate 202 may correspond to any portion of the metal layers 102 of FIG. 1 and/or any portion of the metal vias 104 of FIG. 1. As shown in the illustrated example, the supramolecular bonding layer 200 that has been grafted to the copper substrate 202 includes multiple discrete polymer molecules 204 that have a generally linear structure defined by a main polymer chain or backbone 206 that extends between an R1 functional group 208 and an R2 functional group 210. Further, each of the polymer molecules 204 includes one or more R3 functional groups 212 that are side-tethered to the polymer chain 206 between the ends of the chain 206 where the R1 and R2 groups 208, 210 are located. For purposes of illustration, individual polymer repeat units 214 of the polymer chain 206 are represented by large circles, the R1 groups 208 are represented by triangles, the R2 groups 210 are represented by squares, and the R3 groups 212 are represented by small circles that are shown attached to the polymer chain 206 by a line. The supramolecular bonding layer 200 is also sometimes referred to herein as a polymeric bonding layer because it is made up of polymer molecules 204.

Several classes of chemical species can be utilized to create the base polymer structure (e.g., the base polymer chain 206). Further, each of the functional groups R1, R2, and R3 can be independent of the others because the desired functional groups can be incorporated onto the polymer chain 206 via post-functionalization or, alternatively, via copolymerization using a different backbone along a different portion of the polymer chain 206. Thus, the particular structure of the supramolecular bonding layer 200 is highly flexible to enable the selection of many different possible functional groups having the particular characteristics needed for any given application. For instance, in some examples, the polymer repeat units 214 of the polymer chain 206 include and/or are a derivative of polysiloxane, poly(methyl methacrylate), poly(N-vinyl acetamide), polyvinylidene fluoride, polystyrene, and/or any other suitable material. In some examples, the polymer chain 206 material is selected with a relatively low molecular weight. More particularly, in some examples, the polymer chain 206 material has a molecular weight that is less than the critical entanglement molecular weight (e.g., M_{w}<M_{c}). Further, in some examples, the polymer chain 206 material is selected to have a relatively low glass transition temperature (T_{g}) (e.g., less than 30° C. to allow for ambient processing conditions).

While the polymer chain 206 may be a homopolymer, examples disclosed herein are not so limited. Rather, as noted above, in some examples, the polymer chain 206 is copolymerized with different types of backbone structures. Further, the different polymer backbone structures in such examples can be combined in a random manner or in a particular order as needed to enable the viability of the polymer synthesis with the particular functionalities selected for the R1, R2, and R3 groups 208, 210, 212.

As shown in FIG. 2, the individual polymer molecules 204 are attached or grafted to a bonding surface 216 of the copper substrate 202 with the R1 group 208. In this example, the R1 group 208 is a strong electron-donating group to energy-favorably bond with the copper substrate 202 to form a coordination complex with copper ions on the copper bonding surface 216. More particularly, in some examples, the R1 group 208 includes and/or is a derivative of azoles and/or other heterocyclic compounds (e.g., imidazole, pyrimidine, indazole, histidine, etc.), thiol, phosphate, cyanoacrylate, amides, imides, hydroxyl, amines, phosphines, thiolate, thioacetate, disulfide, alkyl azide, aryl azide, nitrile, phosphate, silyl, alkyl and/or other phosphonate ester, phosphonamide, sulfonamides, sulfenate, sulfinate, sulfonate, boronic acid, phosphonic acids, carboxylic acids, phosphorous dichloride, alkenes, alkynes, and/or any other suitable material.

In illustrated example of FIG. 2, the R1 group 208 is end-tethered to the polymer chain 206, such that each polymer molecule 204 is oriented to extend away from the copper substrate 202 in a direction generally perpendicular to the bonding surface 216. The resulting substantially uniform projection of strands of polymer extending away from the bonding surface 216, as shown in FIG. 2, somewhat resemble the bristles on a brush. Accordingly, the supramolecular bonding layer 200 is sometimes referred to as a brush layer or as having a brush layer structure. The relatively uniform brush-like orientation of the polymer molecules 204 is facilitated by the low glass transition temperature (T_{g}) and low molecular weight (M_{w}) of the polymer chain 206 as mentioned above. In particular, the low T_{g} enables relatively high mobility of the discrete polymer chains 206 so that they can rearrange relative to one another to become oriented generally perpendicular to the bonding surface 216 as shown in FIG. 2. Furthermore, the low M_{w} (e.g., below Mc) reduces (e.g., avoids) entanglement of the polymer chains 206, thereby enabling a compact, self-assembled structure.

Due to the generally perpendicular nature of the linear polymer molecules 204 relative to the bonding surface 216, the example supramolecular bonding layer 200 of FIG. 2 has a thickness that generally corresponds to the length of the individual polymer molecules 204. However, the particular thickness of the supramolecular bonding layer 200 further depends on the chemical composition of the polymer molecules 204 and the resulting way in which the different polymer molecules 204 interact with one another. In some examples, the thickness of the supramolecular bonding layer 200 ranges from approximately 3 nm to 20 nm (±3σ).

In the illustrated example, the R2 group 210 is end-tethered to the polymer chain 206 at an opposite end to that of the R1 group 208. As a result, the orientation of the chains 206 extending away from the copper surface 216 position the R2 group 210 near a surface of the supramolecular bonding layer 200 that is distal to the copper surface 216. In this manner, the R2 group 210 on each polymer molecule 204 is favorably positioned to bond with an organic dielectric layer subsequently added. More particularly, in some examples, the R2 group 210 is selected to form strong covalent bonds with an organic dielectric during vacuum lamination and post-cure operations. FIG. 4 illustrates the results of the R2 group 210 on each polymer molecule 204 in FIG. 2 becoming a reacted R2 group 404 (represented by the shaded squares) that has bonded with the dielectric layer 402. In this example, the dielectric layer 402 of FIG. 4 may correspond to any portion of the organic dielectric layers 112 of FIG. 1.

While the R2 group 210 is selected to bond with the dielectric layer 402, in some examples, the R2 group 210 is also selected to be chemically inert to the rest of the polymer molecule 204 as well as the copper bonding surface 216. Selecting the R2 group 210 to be inert to the rest of the polymer molecule 204 further serves to achieve the favorable orientation of the polymer molecules 204 as shown in FIG. 2 because the R2 group 210 remains unreactive during the deposition or grafting of the supramolecular bonding layer 200 to the copper surface 216. As a result, the R2 group 210 will not form intramolecular and/or intermolecular bonds and/or disordered three-dimensional stack-ups, which are leading causes of defects and/or low bonding densities that can be observed using past organic adhesion promotor techniques as discussed above. In some examples, the R2 group 210 includes and/or is a derivative of amine, carboxylic acid, epoxide, alkene, and/or any other suitable material.

In some examples, the side groups on the polymer molecules 204 (e.g., the R3 groups 212) are also selected to remain unreactive during the initial deposition or grafting process. Therefore, as with the R2 group 210, the R3 group 212 will not form intramolecular and/or intermolecular bonds and/or disordered three-dimensional stack-ups. However, the R3 group 212 becomes chemically relevant during subsequent processing (e.g., via heating and/or catalyzing) to promote the cross-linked bonding of different ones of the R3 groups 212 on different ones of the polymer chains 206. In some examples, not all of the R3 groups 212 will become cross-linked during this initial cross-linking process, but at least some will become cross-linked as represented by the darkened cross-linked R3 groups 302 shown in FIG. 3. Further, in some examples, additional ones of the R3 groups 212 may become cross-linked during subsequent processing associated with the addition or lamination of the dielectric layer 402. Thus, as illustrated in FIG. 4, all of the R3 moieties of the supramolecular bonding layer 200 are shown as being cross-linked R3 groups 302 in the illustrated example of FIG. 4. The formation of the cross-linked R3 groups 302, both during the initial cross-linking process and the subsequent processes, serves to increase the density of the supramolecular bonding layer 200.

In some examples, not all of the R3 groups 212 will become cross-linked even after the dielectric lamination process. In some such examples, any remaining R3 moieties that did not become cross-linked can serve as a reactive group (in combination with R2) to bond with the organic matrix of the dielectric layer 402 during a final full cure process. In some examples, the R3 group 212 includes and/or is a derivative of epoxide, alkene, amine, carboxylic acid, zwitterion, azole family or any heterocycles, thiol, phosphate, cyanoacrylate, amides, imides, acryloxyethyl, and/or any other suitable moiety capable of being self-polymerized (e.g., cross-linked) under heated/catalyzed conditions.

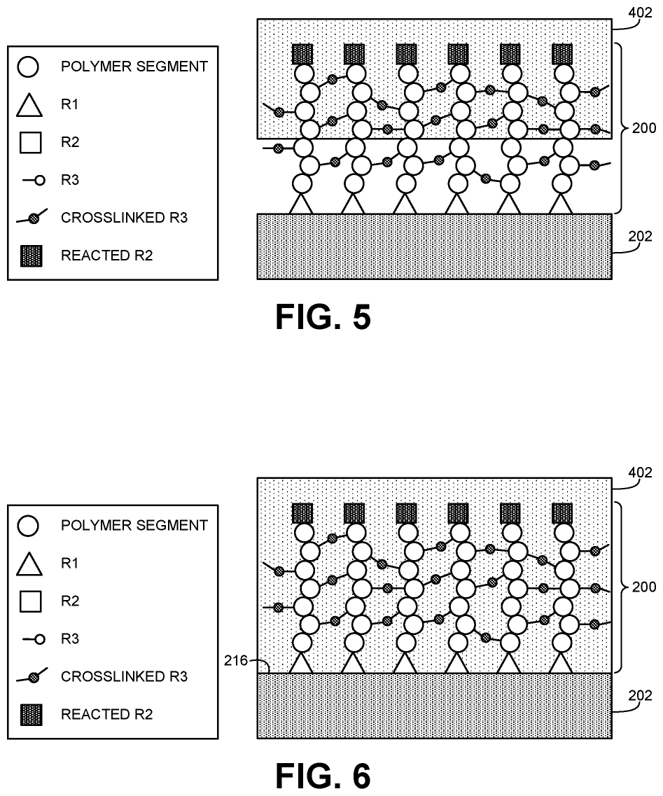

As mentioned above, FIGS. 4-6 represent three alternative example modes of bonding between the dielectric layer 402 and the supramolecular bonding layer 200. The different modes of bonding depend upon the chemical compatibility (e.g., miscibility and/or solubility) between the dielectric layer 402 and the supramolecular bonding layer 200. More particularly, FIG. 4 represents a scenario in which the dielectric layer 402 is non-permeable to the supramolecular bonding layer 200 and, therefore, remains separate from the supramolecular bonding layer 200 (other than at the bonding interface). Thus, as shown in the illustrated example, the supramolecular bonding layer 200 separates the copper substrate 202 from the dielectric layer 402. FIG. 5 represents a scenario in which the dielectric layer 402 is semi-permeable to the supramolecular bonding layer 200 and, therefore, partially integrated within the matrix structure of the supramolecular bonding layer 200. FIG. 6 represents a scenario in which the dielectric layer 402 is fully permeable to the supramolecular bonding layer 200 and, therefore, substantially (e.g., fully) integrated within the matrix structure of the supramolecular bonding layer 200. Thus, as shown in the illustrated example of FIG. 6, the dielectric layer 402 is sufficiently integrated with the supramolecular bonding layer 200 to be in direct contact with the surface 216 of the copper substrate 202. The illustrated examples in FIGS. 4-6 are idealized and provided for purposes of illustration. Thus, in some examples, though the dielectric layer 402 may be non-permeable to the supramolecular bonding layer 200 (as represented in FIG. 4), at least some material of the dielectric layer 402 may still extend past the interface between the dielectric layer 402 and the supramolecular bonding layer 200. Likewise, in some examples, though the dielectric layer 402 may be fully permeable to the supramolecular bonding layer 200 (as represented in FIG. 6), there may be some locations along the surface 216 of the copper substrate 202 that are not in direct contact with the dielectric layer 402.

The chemical structure of the polymer molecules 204 in the supramolecular bonding layer 200 of FIGS. 2-6 and the associated functional groups used therein enable the polymer molecules 204 to be highly oriented in a manner comparable to the bristles of a brush as discussed above. However, FIGS. 2-6 are idealized illustrations that involve the R2 and R3 groups being end-tethered to identically structured and identically oriented polymer chains 206. In some examples, different ones of the polymer chains 206 may have different lengths and/or the locations and/or number of the R3 side groups 212 may differ from one polymer molecule 204 to the next. However, polymer molecules 204 having such differences are still able to form a highly oriented and densely packed supramolecular bonding layer 200.

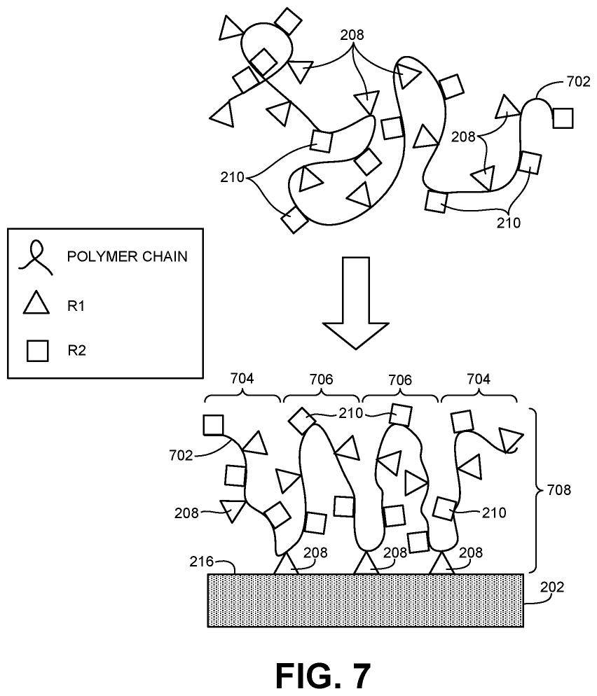

Additionally or alternatively, in some examples, the R1 group 208 and/or the R2 group 210 are side groups tethered to the polymer chain 206 at locations between its ends. In some examples, multiple R1 groups 208 and/or multiple R2 groups 210 are tethered to different locations along the length of the polymer chain 206. Further, in some examples, the R1 and/or R2 groups 208, 210 are tethered to both the ends and the middle of the polymer chain 206. In such examples, the copper-ligand (R1) complexation will still induce a relatively highly oriented structure with segments of the polymer molecules extending away from the copper surface to achieve relatively higher grafting density. This is represented in FIG. 7 in which a single polymer chain 706 includes a plurality of both the R1 and R2 groups 208, 210 at various points along the length of the polymer chain 706. The R3 side group is omitted in FIG. 7 for the sake of clarity.

As represented in the illustrated example of FIG. 7, at least some of the R1 groups 208 along the polymer chain 702 are bonded to the surface 216 of the copper substrate 202. Thus, each of the bonded R1 groups 208 corresponds to a different grafting point along the polymer chain 702. In this example, each of the bonded R1 groups 208 are tethered to the side of the polymer chain 702 and away from the ends of the polymer chain 702. As a result, segments of the polymer chain 702 from the ends to the first bonded R1 group 208 (a first grafting point on the chain closest to an end of the chain 702) correspond to tails 704 on the polymer chain 702, whereas segments of the polymer chain 702 between two adjacent bonded R1 groups 208 (two adjacent grafting points) corresponds to loops 706 of the polymer chain 702. As shown in the illustrated example, both the tails 704 and the loops 706 extend away from the copper surface 216 in a manner that generally corresponds to bristles of a brush. Thus, the polymer chain 702 of FIG. 7 is able to form a supramolecular bonding layer 708 with a brush layer structure that is substantially similar to the idealized supramolecular bonding layer 200 shown in FIGS. 2-6.

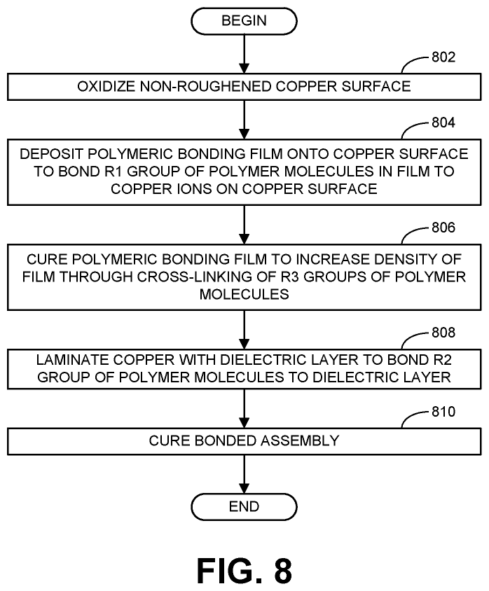

FIG. 8 is a flowchart representative of an example method of manufacturing the example substrate 100 of FIG. 1 using the supramolecular bonding layer 200, 700 of FIGS. 2-6 and/or FIG. 7. In some examples, some or all of the operations outlined in the example method are performed automatically by fabrication equipment that is programmed to perform the operations. Although the example method of manufacture is described with reference to the flowchart illustrated in FIG. 8, many other methods may alternatively be used. For example, the order of execution of the blocks may be changed, and/or some of the blocks described may be combined, divided, re-arranged, omitted, eliminated, and/or implemented in any other way.

The example process begins at block 802 by oxidizing a non-roughened copper surface (e.g., the copper bonding surface 216). As discussed above, the copper surface 216 is non-roughened or smooth to enable high-speed I/O that would not otherwise be possible. At block 804, the example method includes depositing a polymeric bonding film (e.g., the supramolecular bonding layer 200, 700) onto the copper surface 216 to bond an R1 group (e.g., the R1 group 208) of the polymer molecules (e.g., the polymer molecules 204) in the film to copper ions on the copper surface 216. In some examples, the copper surface 216 is oxidized (block 802) in a controlled process prior to film deposition (block 804). However, in other examples, the copper surface 216 is oxidized (block 802) by dissolved oxygen in the chemical solution used during the deposition process (block 804). In some examples, the deposition of the chemical solution is accomplished by a spin-coating process. In some examples, the deposition of the chemical solution is accomplished by a dip-coating process. The copper ions on the copper surface 216 are formed either through the complexation with additives in the chemical solution or through the acidic nature of the solution. With such copper ions formed, the R1 group 208 will bond with copper surface 216 to anchor the polymer molecules 204 to the copper surface at corresponding grafting points. Anchoring the R1 group 208 to the copper surface 216 results in other portions of the polymer molecules 204 being oriented in a direction extending away from (e.g., generally perpendicular to) the copper surface 216. More particularly, the polymer molecules 204 or individual segments thereof (e.g., tails 704 and/or loops 706) extend away from the copper surface 216 because, unlike the R1 group 208 that bonds with the copper surface 216, the R2 and R3 groups 210, 212 are relatively unreactive or inert during this deposition and grafting process so as to be homogenously distributed within and at the surface of the supramolecular bonding layer 200, 700.

At block 806, the example method includes curing the polymeric bonding film (e.g., the supramolecular bonding layer 200, 700) to increase the density of the film through cross-linking of the R3 groups 212 of the polymer molecules 204. In some examples, this is an initial cross-linking process that is intended to partially cross-link the R3 groups. That is, after this initial cross-linking process, at least some of the R3 groups will not be cross-linked. However, cross-linking at least some of the R3 groups 212 improves (e.g., guarantees) the stability of the compact and well organized framework through the formation of intramolecular and intermolecular bonding. Furthermore, such intramolecular and intermolecular bonding densities the overall bonding strength of the supramolecular bonding layer 200, 700, thereby improving the chemical resistance of the film.

At block 808, the method includes laminating (e.g., via heat and pressing in a vacuum environment) the copper with a dielectric layer (e.g., the dielectric layer 112, 402) to bond the R2 group 210 of the polymer molecules 204 to the dielectric layer 112, 402. In some examples, the lamination process can involve multiple layers of copper and multiple layers of dielectric material (as shown in FIG. 1). In some examples, the unreacted R3 group 212 (e.g., the R3 groups that did not cross-link during the initial cross-linking process of block 806) may react and bond with the dielectric layer 112, 402 in addition to the R2 group 210. Whether the R3 group 212 bonds with the dielectric layer 112, 402 depends on the compatibility between the dielectric layer 112, 402 and the supramolecular bonding layer 200. More particularly, in some examples, whether the materials are compatible depends on the miscibility of the supramolecular bonding layer 200 with the organics in the dielectric layer 112, 402 and the solubility of the supramolecular bonding layer 200 in the dielectric laminar solvents. When the materials are fully compatible, the unreacted R3 groups 212 will react and bond with the dielectric material (as shown in FIG. 6). When the materials are not compatible, the unreacted R3 groups 212 will not bond with the dielectric material but instead continue to cross-link among themselves. In such examples, the supramolecular bonding layer 200 bonds with the dielectric layer 112, 402 via the R2 groups 212 at the surface of the supramolecular bonding layer 200 (as shown in FIG. 4). In some examples, the materials may be partially compatible, in which case some of the unreacted R3 groups 212 (in an upper portion of the supramolecular bonding layer 200 closer to the surface distal to the copper substrate 202) will react and bond with the dielectric material while other unreacted R3 groups (in a lower portion of the supramolecular bonding layer 200 proximate to the copper surface 216) will continue to cross-link among themselves

At block 810, the example process includes curing the bonded assembly. In some examples, this is a final full cure process. In some examples, the cross-linking of any unreacted R3 groups is facilitated and/or completed during the application of heat associated with this final cure process.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly that might, for example, otherwise share a same name

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements or method actions may be implemented by, e.g., the same entity or object. Additionally, although individual features may be included in different examples or claims, these may possibly be combined, and the inclusion in different examples or claims does not imply that a combination of features is not feasible and/or advantageous.

From the foregoing, it will be appreciated that example systems, methods, apparatus, and articles of manufacture have been disclosed that enable a non-roughened copper surfaces in a substrate for high speed I/O without compromising the adhesion and reliability of the copper-dielectric interfaces by applying multifunctional supramolecular self-assemblies to densely graft to copper surface in a highly oriented manner.

Further examples and combinations thereof include the following:

Example 1 includes an apparatus comprising a metal layer, a dielectric layer adjacent the metal layer, and a polymeric bonding layer at an interface between the metal layer and the dielectric layer, a polymer molecule in the polymeric bonding layer including an R1 group, an R2 group, and a polymer chain extending between the R1 group and the R2 group, the R1 group different than the R2 group, the polymeric bonding layer bonded to the metal layer via the R1 group, the polymeric bonding layer bonded to the dielectric layer via the R2 group.

Example 2 includes the apparatus of example 1, wherein a portion of the polymer chain extends away from the metal layer, the portion of the polymer chain extending from the R1 group to an end of the polymer chain.

Example 3 includes the apparatus of example 2, wherein the end of the polymer chain is a first end, the R1 group tethered to a second end of the polymer chain such that the portion of the polymer chain corresponds to a full length of the polymer chain, the second end of the polymer chain opposite the first end.

Example 4 includes the apparatus of example 3, wherein the R2 group is tethered to the first end of the polymer chain.

Example 5 includes the apparatus of example 2, wherein the end of the polymer chain is a first end, the R1 group tethered to the polymer chain at a location along a length of the polymer chain between the first end of the polymer chain and a second end of the polymer chain.

Example 6 includes the apparatus of example 5, wherein the polymer molecule includes multiple R1 groups, different ones of the R1 groups tethered to the polymer chain at different locations along the length of the polymer chain.

Example 7 includes the apparatus of example 6, wherein a segment of the polymer chain between two different ones of the R1 groups bonded to the metal layer corresponds to a loop, the loop to extend away from the metal layer.

Example 8 includes the apparatus of any one of examples 1-7, wherein the polymer chain has a molecular weight that is less than an entanglement molecular weight of the polymer chain.

Example 9 includes the apparatus of any one of examples 1-8, wherein the polymer chain has a glass transition temperature that is less than 30° C.

Example 10 includes the apparatus of any one of examples 1-9, wherein the polymer molecule includes a plurality of different ones of an R3 group, the R3 group different than the R1 group and different than the R2 group, different ones of the R3 group to cross-link between at least one of different portions of the polymer molecule or different polymer molecules.

Example 11 includes the apparatus of example 10, wherein ones of the R3 group that are not cross-linked bond with the dielectric layer.

Example 12 includes the apparatus of any one of examples 1-11, wherein the polymeric bonding layer separates the metal layer from the dielectric layer.

Example 13 includes the apparatus of any one of examples 1-11, wherein a material of the dielectric layer is at least partially integrated within a matrix structure of the polymeric bonding layer.

Example 14 includes the apparatus of example 13, wherein the material of the dielectric layer is sufficiently integrated within the matrix structure of the polymeric bonding layer to be in direct contact with the metal layer.

Example 15 includes the apparatus of any one of examples 1-14, wherein a surface of the metal layer to which the R1 group bonds is non-roughened.

Example 16 includes the apparatus of any one of examples 1-14, wherein a first portion of the polymer chain corresponds to a first polymer backbone and a second portion of the polymer chain corresponds to a second polymer backbone, the second polymer backbone different than the first polymer backbone.

Example 17 includes a substrate for a circuit device, the substrate comprising a metal layer having a non-roughened surface, an organic dielectric layer adjacent the surface, and a supramolecular bonding layer at an interface between the surface of the metal layer and the dielectric layer, the supramolecular bonding layer to enable adhesion between the metal layer and the dielectric layer based on different functional groups included in polymer molecules in the supramolecular bonding layer, the different functional groups including a first functional group to bond with the metal layer and a second functional group to bond with the dielectric layer, the first functional group different than the second functional group.

Example 18 includes the substrate of example 17, wherein ones of the polymer molecules include a polymer backbone extending between the first functional group and the second functional group.

Example 19 includes the substrate of any one of examples 17 or 18, wherein the supramolecular bonding layer has a brush layer structure with portions of the polymer molecules oriented to extend away from the surface of the metal layer.

Example 20 includes the substrate of any one of examples 17-19, wherein the first functional group forms a coordination complex with copper ions on the surface of the metal layer.

Example 21 includes the substrate of any one of examples 17-20, wherein the second functional group forms a covalent bond with the dielectric layer.

Example 22 includes the substrate of any one of examples 17-21, wherein ones of the polymer molecules include a plurality of third functional groups, the third functional groups to form cross-links between at least one of different ones of the polymer molecules or different portions of a single one of the polymer molecules.

Example 23 includes the substrate of example 22, wherein the second functional group is chemically inert to the metal layer, the first functional group, the third functional groups, and a polymer chain of the polymer molecules.

Example 24 includes a method of manufacturing a substrate for a circuit device, the method comprising depositing a polymeric bonding film onto a surface of a metal layer, polymer molecules in the polymeric bonding film to bond with the surface of the metal layer via a first functional group included in the polymer molecules, and laminating the metal layer with a dielectric layer, the polymer molecules in the polymeric bonding film to bond with the dielectric layer via a second functional group included in the polymer molecules, the second functional group different than the first functional group.

Example 25 includes the method of example 24, further including, prior to the laminating, curing the polymeric bonding film on the metal layer to facilitate cross-linking between third functional groups included in the polymer molecules, the third functional groups different than the first functional group and the second functional group.

Example 26 includes the method of example 25, wherein ones of the third functional groups that are not cross-linked during the curing of the polymeric bonding film are bonded to the dielectric layer.

Example 27 includes the method of example 25, wherein the laminating results in a bonded assembly, the method further including curing the bonded assembly, ones of the third functional groups that are not cross-linked during the curing of the polymeric bonding film are cross-linked during the curing of the bonded assembly.

Example 28 includes the method of any one of examples 25-27, wherein the depositing and the laminating are performed without roughening the surface of the metal layer.

Although certain example systems, methods, apparatus, and articles of manufacture have been disclosed herein, the scope of coverage of this patent is not limited thereto. On the contrary, this patent covers all systems, methods, apparatus, and articles of manufacture fairly falling within the scope of the claims of this patent.

The following claims are hereby incorporated into this Detailed Description by this reference, with each claim standing on its own as a separate embodiment of the present disclosure.

1. An apparatus comprising:
a metal layer;
a dielectric layer adjacent the metal layer; and
a polymeric bonding layer at an interface between the metal layer and the dielectric layer, a polymer molecule in the polymeric bonding layer including an R1 group, an R2 group, and a polymer chain extending between the R1 group and the R2 group, the R1 group different than the R2 group, the polymeric bonding layer bonded to the metal layer via the R1 group, the polymeric bonding layer bonded to the dielectric layer via the R2 group.

2. The apparatus of claim 1, wherein a portion of the polymer chain extends away from the metal layer, the portion of the polymer chain extending from the R1 group to an end of the polymer chain.

3. The apparatus of claim 2, wherein the end of the polymer chain is a first end, the R1 group tethered to a second end of the polymer chain such that the portion of the polymer chain corresponds to a full length of the polymer chain, the second end of the polymer chain opposite the first end.

4. The apparatus of claim 3, wherein the R2 group is tethered to the first end of the polymer chain.

5. The apparatus of claim 2, wherein the end of the polymer chain is a first end, the R1 group tethered to the polymer chain at a location along a length of the polymer chain between the first end of the polymer chain and a second end of the polymer chain.

6. The apparatus of claim 5, wherein the polymer molecule includes multiple R1 groups, different ones of the R1 groups tethered to the polymer chain at different locations along the length of the polymer chain.

7. The apparatus of claim 6, wherein a segment of the polymer chain between two different ones of the R1 groups bonded to the metal layer corresponds to a loop, the loop to extend away from the metal layer.

8. The apparatus of claim 1, wherein the polymer chain has a molecular weight that is less than an entanglement molecular weight of the polymer chain.

9. The apparatus of claim 1, wherein the polymer chain has a glass transition temperature that is less than 30° C.

10. The apparatus of claim 1, wherein the polymer molecule includes a plurality of different ones of an R3 group, the R3 group different than the R1 group and different than the R2 group, different ones of the R3 group to cross-link between at least one of different portions of the polymer molecule or different polymer molecules.

11. The apparatus of claim 10, wherein ones of the R3 group that are not cross-linked bond with the dielectric layer.

12. The apparatus of claim 1, wherein the polymeric bonding layer separates the metal layer from the dielectric layer.

13. The apparatus of claim 1, wherein a material of the dielectric layer is at least partially integrated within a matrix structure of the polymeric bonding layer.

14. The apparatus of claim 13, wherein the material of the dielectric layer is sufficiently integrated within the matrix structure of the polymeric bonding layer to be in direct contact with the metal layer.

15. The apparatus of claim 1, wherein a surface of the metal layer to which the R1 group bonds is non-roughened.

16. The apparatus of claim 1, wherein a first portion of the polymer chain corresponds to a first polymer backbone and a second portion of the polymer chain corresponds to a second polymer backbone, the second polymer backbone different than the first polymer backbone.

17. A substrate for a circuit device, the substrate comprising:
a metal layer having a non-roughened surface;
an organic dielectric layer adjacent the surface; and
a supramolecular bonding layer at an interface between the surface of the metal layer and the dielectric layer, the supramolecular bonding layer to enable adhesion between the metal layer and the dielectric layer based on different functional groups included in polymer molecules in the supramolecular bonding layer, the different functional groups including a first functional group to bond with the metal layer and a second functional group to bond with the dielectric layer, the first functional group different than the second functional group.

18. The substrate of claim 17, wherein ones of the polymer molecules include a polymer backbone extending between the first functional group and the second functional group.

19. The substrate of claim 17, wherein the supramolecular bonding layer has a brush layer structure with portions of the polymer molecules oriented to extend away from the surface of the metal layer.

20. The substrate of claim 17, wherein the first functional group forms a coordination complex with copper ions on the surface of the metal layer.

21. The substrate of claim 17, wherein the second functional group forms a covalent bond with the dielectric layer.

22. The substrate of claim 17, wherein ones of the polymer molecules include a plurality of third functional groups, the third functional groups to form cross-links between at least one of different ones of the polymer molecules or different portions of a single one of the polymer molecules.

23. The substrate of claim 22, wherein the second functional group is chemically inert to the metal layer, the first functional group, the third functional groups, and a polymer chain of the polymer molecules.

24. A method of manufacturing a substrate for a circuit device, the method comprising:
depositing a polymeric bonding film onto a surface of a metal layer, polymer molecules in the polymeric bonding film to bond with the surface of the metal layer via a first functional group included in the polymer molecules; and
laminating the metal layer with a dielectric layer, the polymer molecules in the polymeric bonding film to bond with the dielectric layer via a second functional group included in the polymer molecules, the second functional group different than the first functional group.

25. The method of claim 24, further including, prior to the laminating, curing the polymeric bonding film on the metal layer to facilitate cross-linking between third functional groups included in the polymer molecules, the third functional groups different than the first functional group and the second functional group.

26-28. (canceled)
